(19) United States
(12) Patent Application Publication
(10) Pub. No.: US 2010/0051339 A1
(43) Pub. Date: Mar. 4, 2010

(54) CIRCUIT BOARD

(75) Inventors: WEN-CHIN OU, Tu-Cheng (TW); MING-LIANG YANG, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/277,243

(22) Filed: Nov. 24, 2008

(30) Foreign Application Priority Data
Sep. 2, 2008 (CN) 200810304344.6

(51) Int. Cl. H05K 1/02

(52) U.S. Cl. 174/260; 174/261

(57) ABSTRACT

A circuit board includes a wiring layer, a first electronic component, a second electronic component, and a pad matrix. The first electronic component is mounted on the wiring layer and includes a number of first terminals. The second electronic component is mounted on the wiring layer and includes a number of second terminals corresponding to the first terminals. The pad matrix is formed on the wiring layer. The pad matrix includes a number of pads, each two adjacent pads have one pad electrically connected to a first terminal and the other pad electrically connected to a second terminal.

### TECHNICAL FIELD

The present invention relates to circuit boards, and particularly to a circuit board having changeable functionality.

### DESCRIPTION OF THE RELATED ART

Typically, circuit board pads and wiring layout are standardized. Components and other electronic elements are connected in a standardized design layout on the circuit board. The inputs and outputs of components are connected within the parameters of the standardized pads and wiring layout and thus the functionality of the components are restricted to their original designed purpose. As a result, the circuit board and the components functionality are restricted.

What is needed, therefore, is a circuit board which can overcome the above-described problem.

### BRIEF DESCRIPTION OF THE DRAWINGS

Many aspects of the present circuit board can be better understood with references to the accompanying drawings. The components in the drawing are not necessarily drawn to scale, the emphasis instead being placed upon clearly illustrating the principles of the present circuit board.

FIG. 1 is a schematic plan view of a circuit board according to a first exemplary embodiment.

FIG. 2 is a schematic plan view of a circuit board according to a second exemplary embodiment.

FIG. 3 is a schematic plan view of a circuit board according to a third exemplary embodiment.

### DETAILED DESCRIPTION OF THE EMBODIMENTS

Embodiments of the present invention will now be described in detail below, with references to the accompanying drawings.

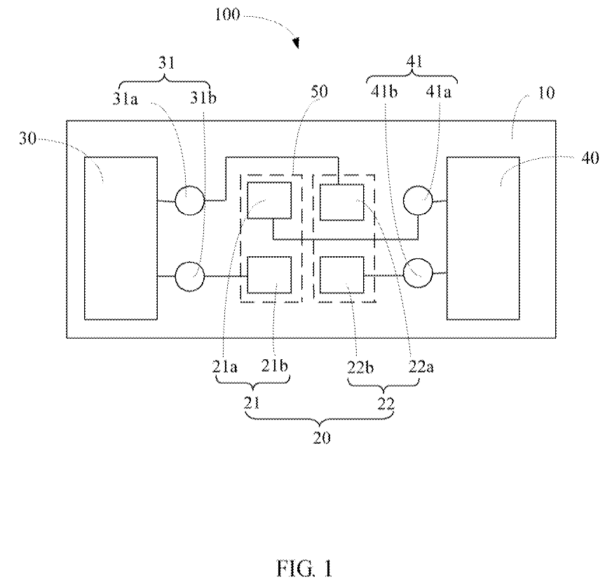

Referring to FIG. 1, a circuit board 100 according to a first exemplary embodiment is shown. The circuit board 100 includes a wiring layer 10, a pad matrix 20, a first electronic component 30, and a second electronic component 40. The pad matrix 20 is formed on the wiring layer 10, and includes a number of pads. The first electronic component 30 and the second electronic component 40 are mounted on the wiring layer 10.

The first electronic component 30 includes a first terminal group 31 having a number of terminals. The second electronic component 40 includes a second terminal group 41 with the number of terminals corresponding to the first terminal group 31. In the present embodiment, the first terminal group 31 includes two terminals 31a and 31b, and the second terminal group 41 includes two terminals 41a and 41b. When the terminal 31a is electrically connected to the terminal 41a and the terminal 31b is electrically connected to the terminal 41b, the circuit board 100 would have a first function. When the terminal 31a is electrically connected to the terminal 41b and the terminal 31b is electrically connected to the terminal 41a, the circuit board 100 would have a second function.

The pad matrix 20 includes a first pad row 21 extending along a first direction and a second pad row 22 parallel to the first pad row 21. The first pad row 21 has two pads 21a and 21b arranged linearly along the first direction, and the second pad row has two pads 22a and 22b arranged linearly along the first direction too. The distance between each two adjacent pads are uniform, so that, each pads of the pads 21a, 21b, 22a, and 22b can be electrically connected to each of the adjacent pads thereof by a surface mount element 50. The surface mount element 50 can be a wire, a resistor, an inductor, or other electronic elements. In the present embodiment, the pads 22a and 21b are connected to the terminals 31a and 31b of the first electronic component 30 respectively, the pads 21a and 22b are connected to the terminals 41a and 41b of the electronic component 40 respectively. So, each of the terminals 31a and 31b can be electrically connected to either of the terminals 41a and 41b by a surface mount element 50. Accordingly, by changing the position of the surface mount elements 50, the circuit board 100 can realize the first function or the second function.

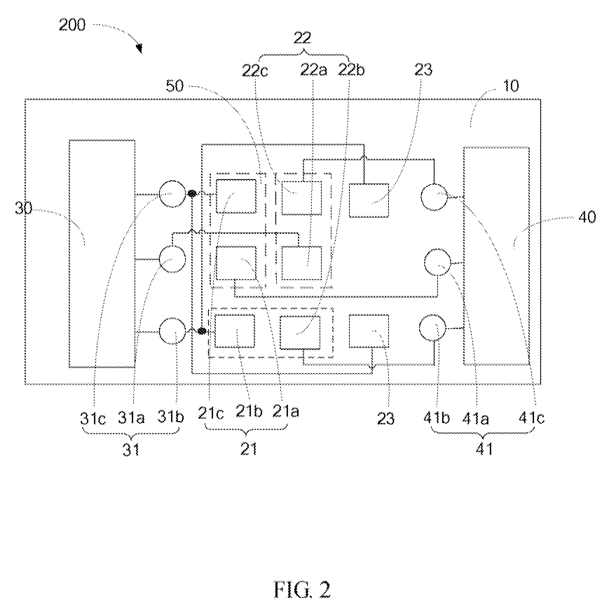

Referring to FIG. 2, a circuit board 200 according to a second exemplary embodiment is shown. The circuit board 200 is similar to the circuit board 100 of the first exemplary embodiment. The differences between the circuit board 200 and the circuit board 100 is that, in the circuit board 200, the first terminal group 31 further includes a terminal 31c adjacent to the terminal 31a and away from the terminal 31b, correspondingly, the second terminal group 41 further includes a terminal 41c, the first pad row 21 further includes a pad 21c, and the second pad row 22 further includes a pad 22c. The pad 21c is electrically connected to the terminal 31c of the first terminal group 31, and the pad 22c is electrically connected to the terminal 41c of the second terminal group 41. Therefore, the pads that are adjacent to a pad that is electrically connected to a terminal of the electronic component 30 are electrically connected to the electronic component 40, and the pads adjacent to the pad electrically connected to a terminal of the electronic component 40 are electrically connected to the electronic component 30.

The circuit board 200 further includes two auxiliary pads 23 formed on the wiring layer 10. One of the pads 23 is formed adjacent to the pad 22b and is electrically connected to the terminal 31c of the first electronic component 30, and the other pad 23 is formed adjacent to the pad 22c and is electrically connected to the terminal 31b of the first electronic component 30. Each of the terminals of the first electronic component 30 can be electrically connected to any of the terminals of the second electronic component 40, and each of the terminals of the second electronic component 40 can be electrically connected to any of the terminals of the first electronic component 30.

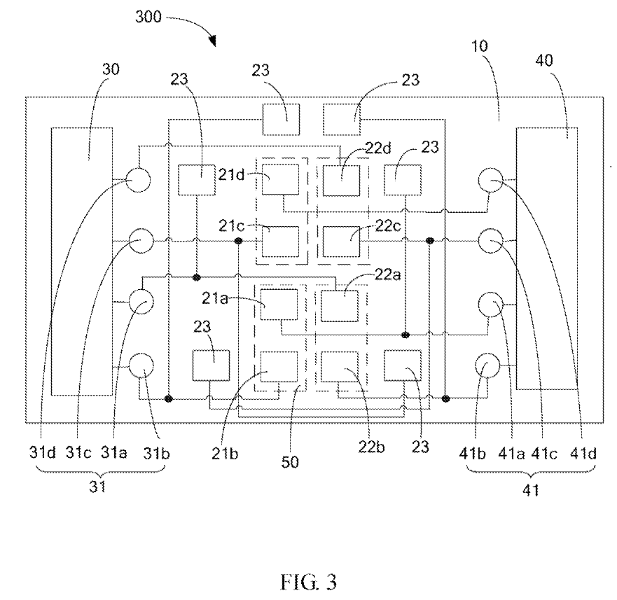

Referring to FIG. 3, a circuit board 300 according to a third exemplary embodiment is shown. The circuit board 300 is similar to the circuit board 200 of the second exemplary embodiment. The differences between the circuit board 300 and the circuit board 200 is that, in the circuit board 300, the first terminal group 31 further includes a terminal 31 d adjacent to the terminal 31c and away from the terminal 31a, correspondingly, the second terminal group 41 further includes a terminal 41d, the first pad row 21 further includes a pad 21d, and the second pad row 22 further includes a pad 22d. The pad 21d is electrically connected to the terminal 41d of the second terminal group 41, and the pad 22d is electrically connected to the terminal 31d of the first terminal group 31. The circuit board 300 also includes additional auxiliary pads 23 than that of the circuit board 200 of the second exemplary embodiment to increase selectable connections between the first electronic component 30 and the second electronic component 40.

While certain embodiments have been described and exemplified above, various other embodiments will be apparent to those skilled in the art from the foregoing disclosure. The present invention is not limited to the particular embodiments described and exemplified, and the embodiments are capable of considerable variation and modification without departure from the scope of the appended claims.

What is claimed is:

1. A circuit board comprising:
a wiring layer;
a first electronic component mounted on the wiring layer, the first electronic component comprising a plurality of first terminals;
a second electronic component mounted on the wiring layer, the second electronic component comprising a plurality of second terminals corresponding to the plurality of the first terminals; and
a pad matrix formed on the wiring layer, the pad matrix comprising a plurality of pads, one of the two adjacent pads is electrically connected to one of the plurality of first terminals and the other of the two adjacent pads is electrically connected to one of the plurality of second terminals.

2. The circuit board as claimed in claim 1, wherein the each two adjacent pads is connected by a surface mount element.

3. The circuit board as claimed in claim 1, wherein the pad matrix comprising a first pad row having a plurality of first pads and a second pad row having a plurality of second pads, the first pad row is parallel to the second pad row.

4. The circuit board as claimed in claim 3, wherein the first pad row has two first pads and the second pad row has two second pads.

5. The circuit board as claimed in claim 3, wherein the first pad row has three first pads and the second pad row has three second pads.

6. The circuit board as claimed in claim 5, further comprising two auxiliary pads formed adjacent to the second pads at two end of the second pad row respectively, the auxiliary pad adjacent to the second pad at an end of the second pad row and the first pad furthest away from the second pad at the end of the second pad row being electrically connected to one first terminal.

7. The circuit board as claimed in claim 3, wherein the first pad row has four first pads and the second pad row has four second pads.

8. A circuit board comprising:
a wiring layer capable of disposing a first electronic component and a second electronic component thereon, the first electronic component comprising a plurality of first terminals, the second electronic component comprising a plurality of second terminals corresponding to the plurality of the first terminals; and
a pad matrix formed on the wiring layer, the pad matrix comprising a plurality of pads, each two adjacent pads having one pad electrically connected to a first terminal and the other pad electrically connected to a second terminal.

9. The circuit board as claimed in claim 8, wherein the each two adjacent pads is connected by a surface mount element.

10. The circuit board as claimed in claim 8, wherein the pad matrix comprising a first pad row having a plurality of first pads and a second pad row having a plurality of second pads, the first pad row is parallel to the second pad row.

11. The circuit board as claimed in claim 10, wherein the first pad row has two first pads and the second pad row has two second pads.

12. The circuit board as claimed in claim 10, wherein the first pad row has three first pads and the second pad row has three second pads.

13. The circuit board as claimed in claim 12, further comprising two auxiliary pads formed adjacent to the second pads at two end of the second pad row respectively, the auxiliary pad adjacent to the second pad at an end of the second pad row and the first pad furthest away from the second pad at the end of the second pad row being electrically connected to one first terminal.

14. The circuit board as claimed in claim 10, wherein the first pad row has four first pads and the second pad row has four second pads.
